(19) United States
(12) Patent Application Publication
(10) Pub. No.: US 2015/0214582 A1
(43) Pub. Date: Jul. 30, 2015

(54) BATTERY AND METHOD FOR DETERMINING THE AGEING STATE OF A BATTERY

(71) Applicant: Hella KGaA Hueck & Co., Lippstadt (DE)

(72) Inventors: Volker SKWAREK, Wesenberg (DE); Ole MORISSE, Bremen (DE)

(21) Appl. No.: 14/610,748

(22) Filed: Jan. 30, 2015

(30) Foreign Application Priority Data
Jan. 30, 2014 (DE) 102014001260.3

(51) Int. Cl. H01M 10/48; G01R 31/36

(52) U.S. Cl. CPC H01M 10/48; H01M 10/484; G01R 31/3679; G01R 31/3634

(57) ABSTRACT

With a battery with two electrodes, at least one separator, at least one reference electrode and an electrolyte, conclusions are to be drawn on its ageing state through measuring the electro-chemical properties. This is achieved by the reference electrode being in contact with the separator, and the reference electrode having a device assigned to it for measuring the impedance.

### BACKGROUND OF THE INVENTION

1. Field of the Invention

The invention relates to a battery with two electrodes, at least one separator, at least one reference electrode and an electrolyte. Further the invention relates to a method for determining the ageing state of a battery.

2. Brief Discussion of the Related Art

A battery in terms of the invention is understood to be a galvanic cell, in particular a rechargeable secondary cell or an accumulator. Batteries of the kind mentioned in the beginning are, above all, used in areas in which energy demand is high, whilst batteries must not be very large and not heavy. One area in which size and weight of the battery matter, is electro-mobility. Here the weight of the battery has an immediate impact on the energy demand of the vehicle. A battery type with a very high energy density is the lithium-ion battery. This is also characterised in that it is thermally stable and not subject to a memory effect. Apart from its use in the area of electro-mobility lithium-ion batteries are used above all in mobile devices.

As part of ongoing developments in the area of electro-mobility it is not only the physical properties of the battery which are of great importance but also the monitoring of the battery state. Therefore information on the charge state of the battery and on its ageing state is essential for its daily use. Devices and methods for the state diagnosis of a battery or a battery system are already known and commercially used.

For example, the U.S. 2012/0263986 A1 has disclosed a rechargeable lithium-ion battery with at least one reference electrode for state diagnosis. A battery system with one or more lithium-ion batteries is described, wherein each individual battery comprises one or more reference electrodes. Each reference electrode is electrically insulated against the electrodes and equipped with a device for taking electrical measurements. In addition a battery managing system is proposed which comprises a device for monitoring the charge state of the battery and which is supplied with information on the potential difference of the electrodes and the potential between electrode and reference electrode.

The currently used systems for monitoring the state of batteries measure, via the electrodes of the battery or possibly via reference electrodes, variables such as current, voltage and temperature and, from these measured variables, calculate for example the internal resistance of the battery. Using various algorithms information can thus be obtained on the state of the battery. However, the problem in using this system is that these measured variables depend on the ageing state of the battery and that the predicted state may thus, depending on the ageing state, deviate from the actual state.

Especially in the area of electro-mobility these deviations can lead to problems since conclusions on the remaining range of the vehicle are drawn via the battery state. Here in particular high-precision measurements from which reliable statements may be derived are very important.

### SUMMARY OF THE INVENTION

The invention is therefore based on the requirement to propose a battery of the kind mentioned in the beginning, where by measuring electro-chemical properties, conclusions may be drawn as to the ageing state of the battery.

The solution to the requirement is achieved with a battery with the characteristics of claim 1. As regards the method the solution is achieved with a method with the characteristics of patent claim 9. Advantageous implementations of the invention are cited in the sub-claims.

With a battery with two electrodes, at least one separator, at least one reference electrode and an electrolyte, provision is made, according to the invention, for the separator to comprise at least one reference electrode, for the separator to comprise at least one film layer and for the reference electrode to have a device for measuring the impedance assigned to it.

With impedance spectroscopy the dielectric properties of a medium are measured in dependence of the frequency of an external electric field. With the present battery the impedance of an electro-chemical system, here the electrolyte, is examined in dependence of the frequency of the applied alternating voltage. At least one reference electrode is used for measuring the impedance. The reference electrode is placed adjacent to the separator or in touching contact with it or it is integrated with the same. Via the reference electrode it is possible to record the impedance spectrum between the electrodes/between the electrodes and the electrolyte, and thus to detect electro-chemical changes in the system. This may include ageing effects such as deposits and corrosion on the electrodes, but also safety-relevant changes such as the growth of dendrites or mechanical changes of the battery cell, which may lead to an internal short-circuit of the electrodes. Temperature changes are also detectable in the impedance spectrum so that it is also possible with this system to measure the temperature distribution in a battery cell. A basic prerequisite for the function of a lithium-ion battery is the presence of an intermediate layer between the corroding electrolyte solution and the electrodes. This boundary layer entitled Solid Electrolyte Interface (SEI) is created during the first charging cycle of the battery when the electrode and the electrolyte come into contact. The SEI acts as an electronically insulating cover layer and protects the electrodes against the corroding electrolyte solution, but it is permeable for the Li⁺-ions. When the SEI is formed the lithium and the charge carrier are irreversibly connected, wherein this is a self-discharging reaction of the battery. Due to electrolyte molecules diffusing through the SEI the thickness of the SEI increases over time. This self-discharge of the battery as a result of the formation of the SEI progresses over time and is irreversible. Further it is possible for metallic lithium deposits to build up on the anode consisting for example of graphite (so-called Li plating). These ageing processes can be monitored by measuring the impedance between the reference electrodes and the electrodes. A further process, which can be examined by impedance spectroscopy, is the formation of dendrites on the electrodes, where they are created through the separation of metals. Dendrites can grow starting from one electrode to the other, which can lead to the mechanical destruction of the separator as well as to the formation of internal short-circuits between the electrodes. Short-circuits caused by dendrites between the electrodes may, during charging and/or discharging of the battery, lead to overheating and thus to the battery catching fire. Using impedance spectroscopy these safety-relevant aspects can also be recognised at an early stage. The separator comprises at least one film layer. The use of film as a separator is advantageous because films are usually produced on a large scale and therefore, depending on what materials are used, can be manufactured in a cost-effective manner. Due to the large selection of available films made of different materials and with different properties it is easy to adapt separators to different requirements.

In a further development of the invention at least one reference electrode is integrated with at least one film layer. One reference electrode may be directly embedded into the separator film during manufacture. Due to embedding it into the film material the reference electrode is well protected against external influences, e.g. the electrolyte.

In one embodiment at least one of the reference electrodes can be applied, at least in sections, onto a film by printing. Manufacturing the reference electrode by way of printing is particularly cost-effective because only a small quantity of material such as gold, platinum or carbon or conductive organic polymer is required. By using large-scale production processes such as roll-to-roll processes cost efficiency may be further improved.

In one embodiment of the battery the separator consists of at least two film layers and the reference electrode is, at least in sections, arranged between the film layers. Preferably if using several reference electrodes, all reference electrodes are arranged between the film layers. By arranging the reference electrodes in the separator which separates the two cell electrodes from each other, it is possible to take measurements of the impedance between the reference electrodes and the respective cell electrodes. In addition due to the arrangement of the reference electrodes in the separator, manufacture of the battery is time-efficient because the reference electrodes may simply be installed together with the separator in one production step.

In a preferred embodiment of the battery the device for measuring the impedance may comprise at least one impedance converter. Due to the use of an impedance converter it is possible to generate the frequencies relevant for detecting the mechanisms to be monitored in a simple manner. The predominantly used frequencies are low-range frequencies. If using electrically non-conductive material as reference electrodes it is possible to also use higher frequencies for detecting the mechanisms.

In a further development of the battery at least one reference electrode is suitable for measuring the Redox potential and at least one reference electrode has assigned to it a device for measuring the Redox potential of the electrolyte. Thus the Redox potential of the electrolyte in the battery can be directly determined via the reference electrode. The Redox potential changes as the active ions in the electrolyte are reduced, and this is an additional indication of the ageing state of the battery.

Preferably the described battery is a lithium-ion battery. There may be different types of lithium-ion battery. Examples for the different types of a lithium-ion battery are the lithium-polymer battery, the lithium-titanate battery, the lithium air battery, the lithium manganese battery and the lithium-iron-phosphate battery.

A further aspect of the invention relates to a battery system with at least one battery according to one of the preceding claims. In this battery system individual batteries may be switched in series and the ageing and charge state of each individual battery may be monitored through the electrodes and reference electrodes.

With a method for determining the ageing state and the charge state of a battery with at least one reference electrode, which is arranged between the films of the separator, integrated with a film layer of the separator or which is applied to at least one film layer of the separator by way of printing and which has assigned to it a device for measuring the impedance, provision is made according to the invention for the impedance between the electrodes and/or between at least one electrode and at least one reference electrode to be measured for selected frequencies and for the state of the battery and the ageing effects such as for example corrosion or deposits on the electrodes to be ascertained from the measured impedance data. Due to the use of reference electrodes, which are integrated with the separator or which are arranged between two film layers of the separator or which have been applied to a film layer of the separator by way of printing, the impedance spectrum between the electrodes can be measured and conclusions can thus be drawn regarding electro-chemical changes in the system, in particular changes in the electrodes and their boundary layers to the electrolyte. For measuring the impedance alternating voltages of selected frequencies are applied between the electrodes or between at least one electrode and at least one reference electrode. Depending on this external electrical field the impedance of the system is recorded via a sensor system. The frequencies of the alternating voltage are selected such that all relevant frequencies for recognising the mechanisms to be detected, such as corrosion on the electrodes, changes of the SEI or dendrite growth, are covered. The measured impedance data is evaluated by the sensor unit which may comprise an impedance converter. From the evaluated measured impedance data ageing effects such as for example corrosion or deposits on the electrodes can be determined.

In a further development of the method provision is made for the degradation of the SEI layer to be determined from the measured impedance data. By permanently monitoring the measured impedance data and their evaluation, conclusions can be drawn from certain changes in the measured data as to a change in the SEI layer. Excessive degradation of the SEI layer may lead to corrosion of the electrodes through the electrolyte. Any corrosion of the electrodes, which may lead to destruction of the battery, can thus be recognised in good time.

Further provision may be made for the Redox potential of the electrolyte to be determined via reference electrodes. Changes in the Redox potential of the electrolyte point to a disintegration of the electrolyte, which gives an indication as to the ageing of the battery.

Advantageously the power prognosis can be adapted with the method, taking ascertained ageing effects into account. Especially in the area of electro-mobility a reliable prediction of the remaining power potential of a battery is important. In order to be able to accurately predict the power of a battery, the information gained from the measured impedance data on ageing effects of the battery is taken into consideration. This means that reliable information can be obtained a. o. as to the charge state of the battery.

In a further development of the method measured data can be passed to a sensor unit by means of a multiplexing method. In a multiplexing method several measured data can be combined and transmitted via a single line. Due to this multiplexing method the measured signals of several battery cells can be passed to a sensor unit. Thus only one sensor unit is required for evaluating the measured data of different battery cells and their respective activation.

### BRIEF DESCRIPTION OF THE DRAWINGS

An embodiment of the invention, which reveals several inventive features, is shown in the drawing in which

FIG. 1 shows a schematic view of a battery in the form of a pouch bag cell; and

FIG. 2 shows a schematic view of the measuring arrangement in a single cell; and

FIG. 3 shows an explosive view of a battery with a reference electrode integrated with the separator.

### DETAILED DESCRIPTION OF THE PREFERRED EMBODIMENTS

FIG. 1 schematically shows the layer construction of a battery in the form of a pouch bag cell. The negative pole 1 has an arrester 2 assigned to it, which for example consists of copper. The arrestor 2 is provided for discharging the charge carriers. The negative electrode 3 is mounted so as to be in contact the arrestor 2. The negative electrode 3 consists e.g. of graphite, which has lithium atoms embedded in it between the graphite planes. This deposit is called an intercalation compound. The central layers of the battery cell represent a separator which electrically separates the negative and the positive electrode, but at the same time is permeable to the lithium ions. The separator comprises two films 4, 5, between which a reference electrode 6 is arranged. The reference electrode 6 consists for example of gold, platinum, carbon or conductive organic polymers. The positive pole 7 has an arrestor 8 assigned to it which for example consists of aluminium. A positive electrode 9 is in direct electrical contact with the arrestor 8, which electrode consists for example of a lithium metal oxide such as lithium cobalt dioxide.

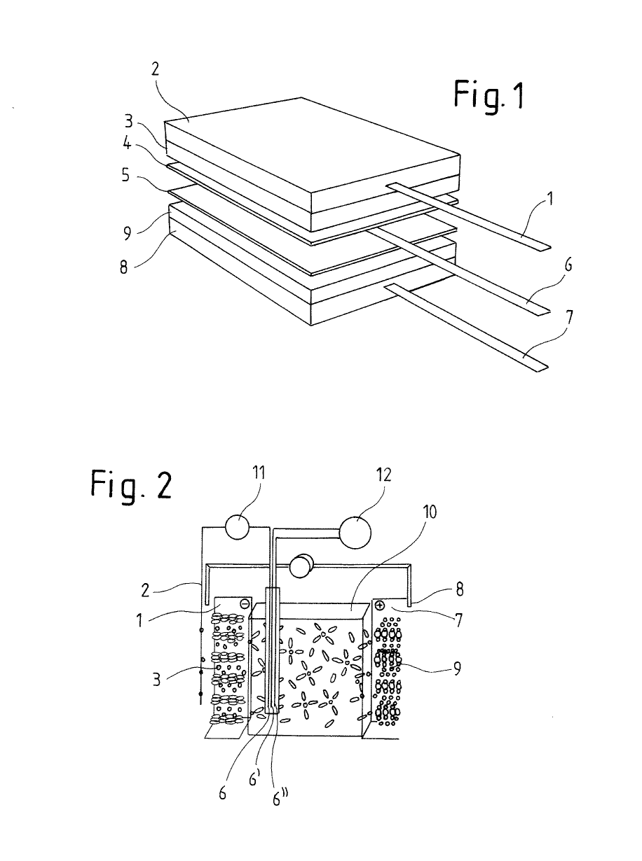

FIG. 2 shows an embodiment for a measuring arrangement of a single cell of FIG. 1. Identical components of the battery are marked with the same reference symbols. In this embodiment the separator, in addition to a reference electrode 6 for measuring the impedance, comprises two further reference electrodes 6′ and 6″ which are suitable for measuring the Redox potential. The reference electrode 6 is connected with an arrestor 2 of the negative pole 1. The region between the electrodes 3 and 9 is filled with an electrolyte 10. A device 11 for measuring the impedance is connected between the reference electrode 6 and the arrestor 2. A measuring device 12 is connected with the reference electrodes 6′ and 6″ for determining the Redox potential of the electrolyte.

Electric energy is stored in a chemical process in a rechargeable lithium-ion battery. Li+-ions can move freely in an electrolyte 10 between the electrodes 3 and 9. If a consumers withdraws energy from the battery, the lithium-ions pass electrons to the negative electrode 3. The electrons reach the positive electrode 9 via the consumer, where they are absorbed by ionised transition metal ions, for example cobalt. In order balance this current flow, Li+-ions flow from the negative electrode 3 to the positive electrode 9.

In a method for determining the ageing state and the charge state of a battery, the impedance between the electrodes 3, 9 is measured by means of a reference electrode 6 which is arranged between the two films 4, 5 or integrated with the separator film. To this end an alternating voltage with selected frequencies is applied to the reference electrode 6 and to one of the electrodes 3 or 9 and the measured impedance data is recorded. Equally it is possible to apply an alternating voltage to the electrodes 3 and 9 and to measure the resulting signal via the reference electrode 6. The measured impedance data is evaluated and conclusions are drawn from the evaluated measured data as to the state of the battery, and ageing effects are determined. Apart from the impedance the Redox potential within the battery may be determined by means of a suitable electrode, and this can also be used for determining ageing effects. The ascertained ageing effects are taken into consideration in the power prognosis of the battery.

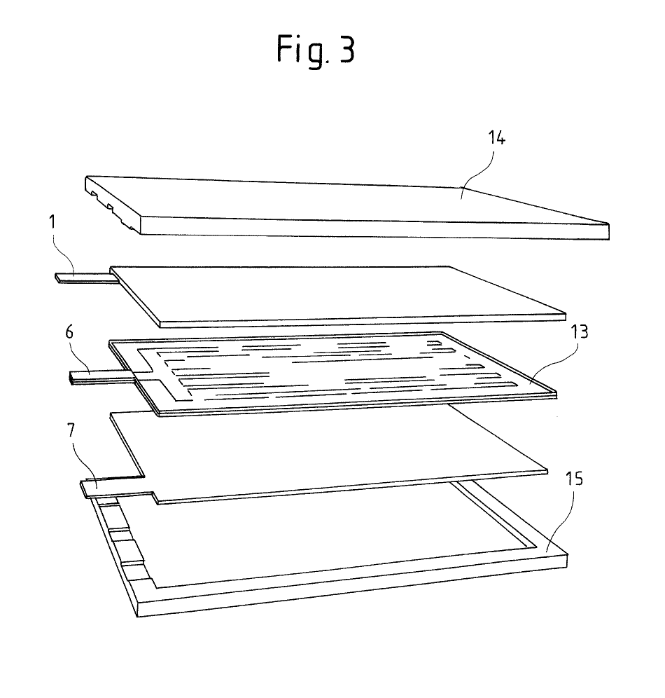

FIG. 3 schematically shows a battery with a separator consisting of a film layer 13. A reference electrode 6 is integrated with the film layer 13. By firmly integrating the reference electrode 6 with the film layer 13, the reference electrode is protected against external influences by e.g. the electrolyte. In the layer-by-layer construction of the battery the film layer 13 is arranged between the negative pole 1 and the positive pole 7. The battery cell is surrounded by a housing consisting of two layers 14, 15.

In the above description all features can be combined in a random selection with the features of the independent claim. The disclosure of the invention is thus not limited to the described or claimed feature combinations, rather all feature combinations meaningful in terms of the invention are to be regarded as disclosed.

1. A battery with two electrodes, at least one separator, at least one reference electrode and an electrolyte,
wherein the separator comprises at least one reference electrode, the separator comprises at least one film layer, and the reference electrode has assigned to it a device for measuring the impedance.

2. The battery according to claim 1, wherein at least one reference electrode is integrated with at least one film layer.

3. The battery according to claim 1, wherein at least one of the reference electrodes is applied, at least in sections, to a film layer by printing.

4. The battery according to claim 1, wherein the separator consists of at least two film layers and the reference electrode is arranged, at least in sections, between the film layers.

5. The battery according to claim 1, wherein the device for measuring the impedance comprises at least one impedance converter.

6. The battery according to claim 1, wherein at least one reference electrode is suitable for measuring a Redox potential and at least one reference electrode has assigned to it a device for measuring the Redox potential of the electrolyte.

7. The battery according to claim 1, wherein the battery is a lithium-ion battery.

8. A battery system with at least one battery according to claim 1.

9. A method for determining the ageing state and the charge state of a battery according to claim 1,
wherein at least one reference electrode which is arranged between the films of the separator, is integrated with a film layer of the separator or is applied by printing to at least one film layer and which has assigned to it a device for measuring the impedance, and
wherein
a) the impedance between the electrodes and/or between at least one of the electrodes and at least one reference electrode is measured at selected frequencies,
b) ageing effects such as e.g. corrosion or deposits on the electrodes are ascertained from the measured impedance data.

10. The method according to claim 9, wherein the degradation of the SEI layer is determined from the measured impedance data.

11. The method according to claim 9, wherein a Redox potential of the electrolyte is additionally determined via suitable reference electrodes.

12. The method according to claim 9, wherein the power prognosis is adapted taking the ascertained ageing effects into account.

13. The method according to claim 9, wherein the measured data of individual battery cells is passed to a sensor unit through a multiplexing method.
